(19) United States
(12) Patent Application Publication
(10) Pub. No.: US 2019/0223318 A1
(43) Pub. Date: Jul. 18, 2019

(54) POWER SUPPLY DEVICE, HEADLIGHT AND MOVING BODY

(71) Applicant: Panasonic Intellectual Property Management Co., Ltd., Osaka (JP)

(72) Inventors: Akio INOUE, Osaka (JP); Hideyuki FUKUDA, Osaka (JP)

(21) Appl. No.: 16/235,224

(22) Filed: Dec. 28, 2018

(30) Foreign Application Priority Data
Jan. 12, 2018 (JP) 2018-003466

(51) Int. Cl. H05K 7/20; F21S 41/14; H05K 1/18; H05K 1/02; F21V 29/508; F21V 29/76; H05K 5/00

(52) U.S. Cl. CPC H05K 7/209; H05K 2201/10022; H05K 1/181; H05K 1/0203; F21V 29/508; F21V 29/76; H05K 5/0008; H05K 2201/10522; H05K 2201/066; H05K 2201/10409; H05K 2201/10015; H05K 2201/1003; H05K 2201/10174; H05K 2201/10166; F21S 41/14

(57) ABSTRACT

A power supply device includes a covering member, at least one high-height component, and at least one low-height component lower than the high-height component. The covering member includes a reference surface, at least one concave portion recessed from the reference surface toward a side opposite to a side of a circuit board in a Z direction, and at least one convex portion projecting from the reference surface toward the side of the circuit board in the Z direction. The at least one high-height component includes at least one high-height thermally connecting component, a tip end portion of which is thermally connected to a bottom surface of the concave portion, and the at least one low-height component includes at least one low-height thermally connecting component, a tip end portion of which is thermally connected to a tip end surface of the convex portion.

### CROSS REFERENCE TO RELATED APPLICATION

The entire disclosure of Japanese Patent Application No. 2018-003466 filed on Jan. 12, 2018, including the specification, claims, drawings, and abstract, is incorporated herein by reference in its entirety.

### TECHNICAL FIELD

The present disclosure relates to a power supply device, and relates, for example, to a power supply device used to light up a headlight of a moving body. Moreover, the present disclosure relates to a headlight including a power supply device and a moving body including a headlight.

### BACKGROUND

Conventionally, as a power supply device, there has been the one described in Japanese Unexamined Patent Application No. 2014-146465. The power supply device is used for supplying power to a headlight of a vehicle. The power supply device properly converts power from a battery of the vehicle, and supplies the converted power to a light source or the like via a connector and wiring.

### SUMMARY

### Technical Problem

A power supply device includes a circuit board and plural electronic components mounted on the circuit board. Moreover, the electronic components are likely to be damaged and experience shortened life thereof due to temperature rise caused by heat generation. In such a background, it is preferable to provide a cover to the power supply device for covering the electronic components and to thermally connect tip end portions of the electronic components with an inner surface of the cover, because heat removal in the electronic components is accelerated.

However, the plural electronic components include two or more electronic components having different height. Consequently, there is a need to form, inside the cover, an inner surface with heights corresponding to the heights of the respective electronic components. However, if convex portions corresponding to the tip ends of the respective electronic components in the height direction are provided on the inner surface of the cover in a flat surface shape, the height of the convex portion corresponding to the low electronic component is increased. Accordingly, large tensile stress occurs on the cover, and thereby the cover is likely to be broken. Moreover, if concave portions corresponding to the respective electronic components are provided to the inner surface of the cover in the flat surface shape, depths of the concave portions corresponding to the high electronic component are increased. Accordingly, in this case, deformation of the cover is increased, to thereby cause large tensile stress to the cover, and therefore the cover is likely to be broken.

Therefore, an object of the present disclosure is to provide a power supply device capable of performing heat removal from a tip end side of plural electronic components and capable of suppressing breaking in a heat remover that performs heat removal from the tip end side.

### Solution to Problem

To solve the above-described problem, a power supply device related to the present disclosure is a power supply device that converts input power to generate output power, and the power supply device includes: a first member including a circuit board placement surface; a circuit board placed on the circuit board placement surface of the first member; a second member that covers a side opposite to a side of the first member of the circuit board in a thickness direction; and plural electronic components mounted on the circuit board, wherein the plural electronic components include at least one high-height component and at least one low-height component having a height lower than the high-height component, the second member includes a reference surface, at least one concave portion recessed from the reference surface toward a side opposite to a side of the circuit board in the thickness direction, and at least one convex portion projecting from the reference surface toward the side of the circuit board in the thickness direction, the at least one high-height component includes at least one high-height thermally connecting component, a tip end portion of which is thermally connected to a bottom surface of the concave portion, and the at least one low-height component includes at least one low-height thermally connecting component, a tip end portion of which is thermally connected to a tip end surface of the convex portion.

Note that the circuit board may be directly placed on the circuit board placement surface, or may be placed on the circuit board placement surface with a member interposed. Moreover, when there are plural high-height components, all of the high-height components may be the high-height thermally connecting components thermally connected to the bottom surface of the concave portion. However, some of the plurality of the high-height components may not be thermally connected to the bottom surface of the concave portion. Moreover, when there are plural low-height components, all of the low-height components may be the low-height thermally connecting components thermally connected to the tip end surface of the convex portion. However, some of the plurality of the low-height components may not be thermally connected to the tip end surface of the convex portion.

### Advantageous Effects of Invention

According to the power supply device related to the present disclosure, it is possible to perform heat removal from a tip end side of plural electronic components and to suppress breaking in a heat remover that performs heat removal from the tip end side.

### BRIEF DESCRIPTION OF DRAWINGS

The figures depict one or more implementations in accordance with the present teaching, by way of example only, not by way of limitations. In the figures, like reference numerals refer to the same or similar elements.

An embodiment of the present disclosure will be described based on the following figures, wherein:

FIG. 1 is an exploded perspective view of a power supply device related to an embodiment of the present disclosure;

FIG. 2 is a schematic view of an automobile including a headlight incorporating the power supply device;

FIG. 3 is a partial enlarged cross-sectional view around an engaging projection portion of the power supply device;

FIG. 4 is a perspective view of the power supply device;

FIG. 5 is a perspective view of a covering member of the power supply device as viewed from a back side;

FIG. 6 is a perspective view of the power supply device as viewed from a back side; and

FIG. 7 is a schematic cross-sectional view of a part of the power supply device in a modified example including a middle-height thermally connecting component.

### DESCRIPTION OF EMBODIMENTS

Hereinafter, an embodiment related to the present disclosure will be described in detail with reference to the accompanying drawings. Note that when plural embodiments or modified examples are included in the following description, it is assumed, from the beginning, that a new embodiment is established by suitably combining characteristic portions of those plural embodiments or modified examples. Moreover, in the following description of the embodiments and drawings, an X direction represents an extending direction of radiator fins 12 provided on a heat sink 10, which will be described hereinafter, a Y direction represents an alignment direction of the plural radiator fins 12, and a Z direction represents a thickness direction (a height direction) of a circuit board 30, which will be described hereinafter. The X direction, the Y direction and the Z direction are perpendicular to one another. Moreover, hereinafter, description will be given of a case in which a covering member 50 is disposed on one side of the circuit board 30 and the heat sink 10 is disposed on the other side of the circuit board 30. The covering member 50 side in the Z direction is referred to as an upper side in the Z direction, and the heat sink 10 side in the Z direction is referred to as a lower side in the Z direction. Moreover, in the specification, the requirement “substantially” is met when, roughly speaking, a person can see so. For example, the requirement is met when a person having unassisted or spectacled eyesight of 0.7 or more in both eyes (a value in an eyesight check in Japan) can see so when they view from a position one meter away. For instance, the requirement “substantially symmetry with respect to a plane” is met when, roughly speaking, a person can see things to be symmetrical with respect to a plane. For example, the requirement is met when a person having unassisted or spectacled eyesight of 0.7 or more with both eyes can see the things to be symmetrical with respect to a plane when they view them from a position one meter away. Moreover, of constituents described in the following description, those not described in an independent claim representing the highest concept are arbitrary constituents, not indispensable constituents.

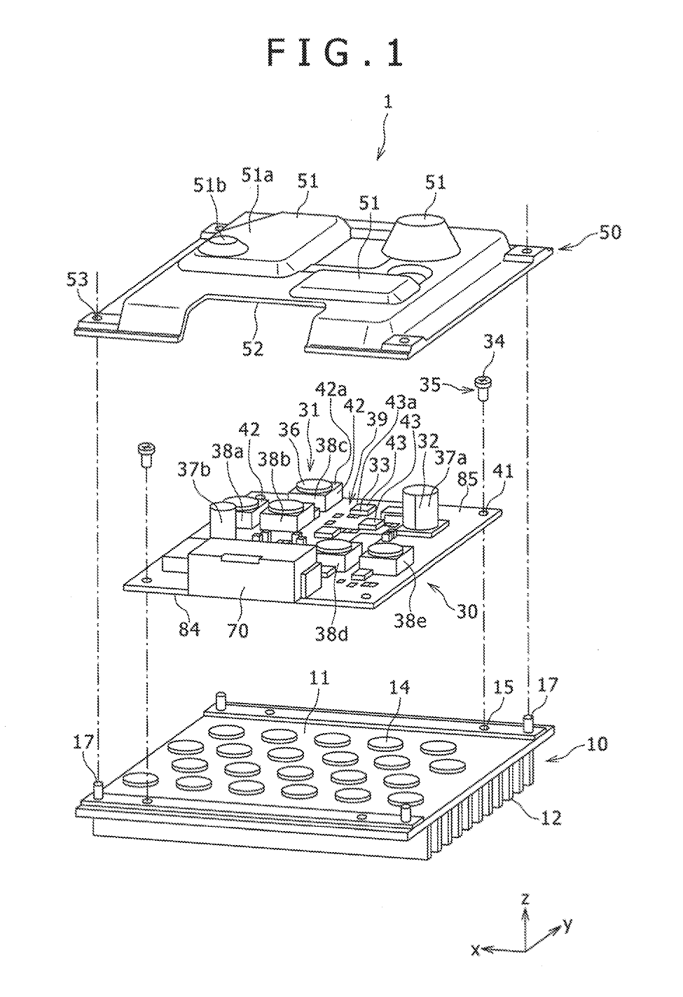

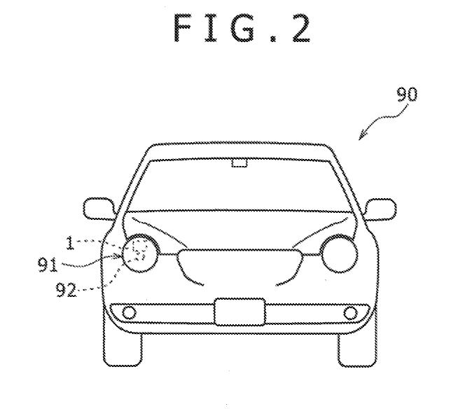

FIG. 1 is an exploded perspective view of a power supply device 1 related to an embodiment of the present disclosure. The power supply device 1 is provided for a headlight of moving bodies, such as, for example, vehicles including an automobile, train, ship or hovercraft. The power supply device 1 properly converts input power from a power source, such as a battery, in accordance with specifications to generate output power, and supplies the generated output voltage to a light source of the headlight. For instance, in an example shown in FIG. 2, the power supply device 1 is incorporated in a headlight 91 of an automobile 90 as an example of a moving body, properly converts input power from a power source, such as a battery of the automobile 90, in accordance with specifications to generate output power, and supplies the generated output voltage to a light source 92 of the headlight 91. The light source 92 can be suitably configured with, for example, LEDs (Light Emitting Diodes) mounted on a circuit board. However, the light source 92 may be configured with other solid-state light emitting elements, such as organic EL (Electro Luminescence) elements or inorganic EL elements. Alternatively, the light source may be configured with an incandescent lamp or a fluorescent light.

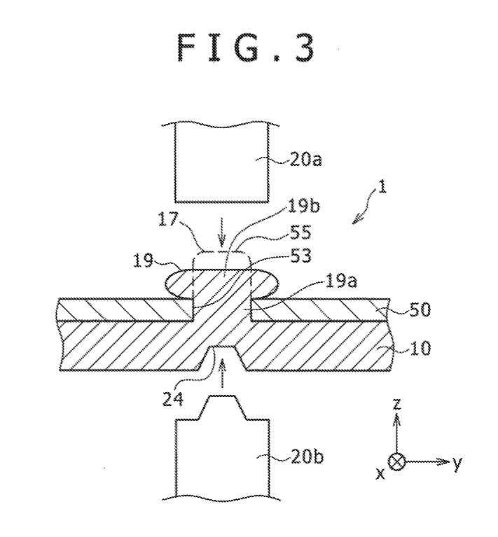

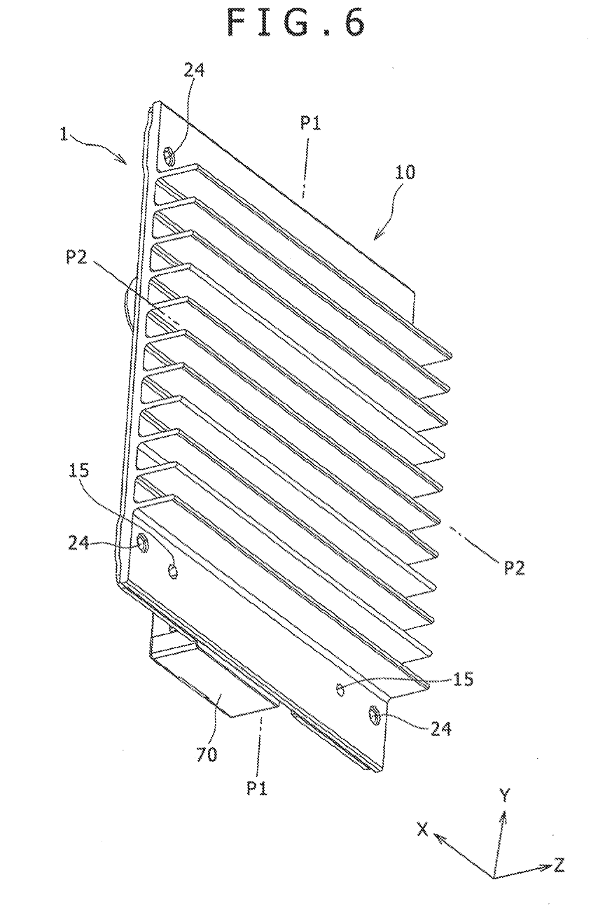

As shown in FIG. 1, the power supply device 1 includes: a heat sink 10 as a first member; a circuit board 30; a covering member 50 as a second member; a connector 70; and plural electronic components 31. The heat sink 10 is configured with a metallic material, such as, for example, aluminum, an aluminum alloy or a steel material. The heat sink 10 has substantially a rectangular shape in a planar view. The heat sink 10 includes plural radiator fins 12 on a lower side in the Z direction and a circuit board placement surface (a surface on which a circuit board is placed) 11, which is a flat surface, on an upper side in the Z direction. The plural radiator fins 12 are disposed in the Y direction at intervals from each other, and each radiator fin 12 extends in the X direction. The radiator fins 12 will be described later in further detail by use of FIG. 6. The heat sink 10 includes columnar-shaped projection portions 17 that project upwardly at four corners thereof. The projection portions 17 are used to integrate the heat sink 10 with the covering member 50. The integration will be described later by use of FIG. 3.

On the circuit board placement surface 11, plural pieces of adhesive radiation gel 14 are substantially uniformly disposed in both the X direction and the Y direction. The radiation gel 14 is provided, when the heat sink 10 is attached to the circuit board 30, to fill in minute gaps at joint portions therebetween, to thereby reduce thermal resistance to heat from the circuit board 30 to the heat sink 10. The radiation gel 14 contains, for example, a base material and particles of metal or metallic oxide (a filler) dispersed in the base material substantially uniformly. The base material is used for ensuring insulation properties and filling in the minute gaps without leaving any space. On the other hand, the filler is configured with particles having high thermal conductivity, and is used for improving heat conductivity. The base material is configured with, for example, a gel (grease) with less viscosity variation from room temperature to high temperature of a certain level, such as silicone. Moreover, the filler is configured with, for example, copper, silver, aluminum, alumina, magnesium oxide, aluminum nitride or mixture thereof, and those single elements or a mixture is dispersed in the base material by a dispersing method commensurate with a particle diameter. Note that as the radiation gel 14, thermosetting resin or the like may be used.

The circuit board 30 is placed on the circuit board placement surface 11 via the plural pieces of adhesive radiation gel 14. The circuit board 30 is configured with, for example, a printed circuit board. The circuit board 30 may have any hardness, and therefore, may be configured with any of a rigid circuit board, a flexible circuit board and a rigid-flexible circuit board. Moreover, the circuit board 30 may have any compositions, and the circuit board 30 is configured with, for example, a paper-phenolic circuit board, a paper-epoxy circuit board, a glass-composite circuit board, a glass-epoxy circuit board, a Teflon circuit board, alumina (ceramics) circuit board, a composite circuit board or others.

The circuit board 30 has screw holes 41, which are through holes, at four corners thereof, and the heat sink 10 has screw holes 15 at corners surrounding the center portion of the circuit board placement surface 11. Screws 35 are screwed into the screw holes 41 and the screw holes 15 from the upper side of the circuit board 30, in such a way that a spring washer (not shown) is held between a top surface of the circuit board 30 and head portions 34. In this manner, the circuit board 30 is fastened to the heat sink 10. The coefficient of linear expansion is different between the circuit board 30 and the heat sink 10, which is made of a metallic material. Consequently, when the circuit board is fastened to the heat sink by a measure other than screwing, there is a possibility that the difference in the coefficient of linear expansion will loosen the fastening. In this embodiment, the looseness is suppressed or prevented by screwing using the spring washer.

Further, the screwing assumes a role of preventing malfunction caused by noise, or preventing electrical leakage. For details, the connector 70 is attached onto the top surface of the circuit board 30. The connector 70 is provided to electrically connect output wiring, through which the current of the converted power flows, to connection wiring or the like that leads to the light source. The connector 70 includes a ground terminal that leads to a grounding conductor. On the circuit board 30, metallic foil (not shown) electrically connecting contact positions of the screws 35 and the ground terminal of the connector 70, and configured with copper foil or others, is provided. Moreover, as will be described later, the covering member 50 is attached to the heat sink 10 to be electrically connected.

By performing screwing, the heat sink 10 is grounded via the screws 35, the metallic foil and the ground terminal, and the covering member 50 is grounded via the heat sink 10, the screws 35, the metallic foil and the ground terminal. As a result, it is possible to dissipate charge in the heat sink 10 and the covering member 50 through the ground connection, and it is thereby possible to prevent overcurrent from flowing into the electronic components due to a lightning strike, or to prevent malfunction due to noise. Further, as a result of the grounding, it is possible to prevent electrical leakage caused by moisture entered inside the power supply device 1.

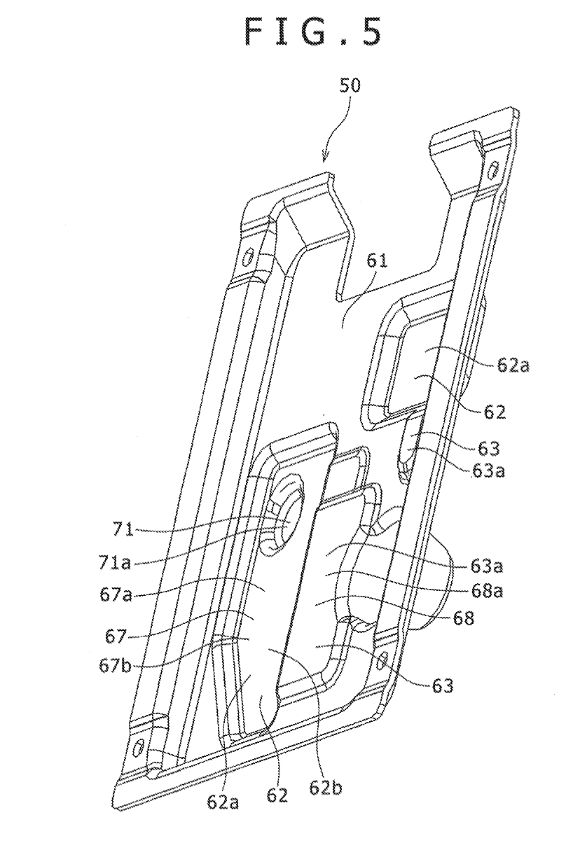

The plural electronic components 31 are mounted on the circuit board 30. The plural electronic components 31 include plural high-height components (components whose height is high) 32 and plural low-height components (components whose height is low) 33. Each high-height component 32 includes a tip end portion positioned above a reference surface, which will be described later using FIG. 5, and each low-height component 33 is positioned below the reference surface. Examples of the plural high-height components 32 include electrolytic capacitors 37a and 37b, coils 38a, 38b, 38c, 38d and 38e, and a large-sized capacitor, and examples of the plural low-height components 33 include a small-sized LC, an FET (a field effect transistor), a diode, a capacitor and a resistor.

The covering member 50 is a lid member including concave portions on a back side thereof, which is formed by, for example, a drawing press process using a sheet metal. The covering member 50 includes plural convex portions 51 projecting upwardly on the upper surface (the front surface) thereof. Moreover, the covering member 50 includes a concave portion 52 corresponding to the connector 70 at a position overlapping the connector 70 as viewed from the Z direction. The covering member 50 has, in a planar view, a shape of a rectangle provided with a small rectangle concave portion, and the connector 70 is disposed in the space of the small rectangle. The covering member 50 includes four through holes 53 provided in four corners. As viewed from the Z direction, the four through holes 53 overlap the four projection portions 17 of the heat sink 10.

On the circuit board 30, the plural electronic components 31 are mounted and the connector 70 is attached. Thereafter, as described above, the circuit board 30 is fastened to the heat sink 10 by use of the screws 35, and subsequently, on the tip end portions of a part of the electronic components 31, pieces of radiation gel 36 are disposed. In FIG. 1, illustration of pieces of radiation gel 36 disposed on the tip end portions of the low-height components 33 is omitted. As the radiation gel 36, the same gel as the above-described adhesive radiation gel 14 can be adopted. As the radiation gel 36, similar to the radiation gel 14, the thermosetting resin or the like may be used.

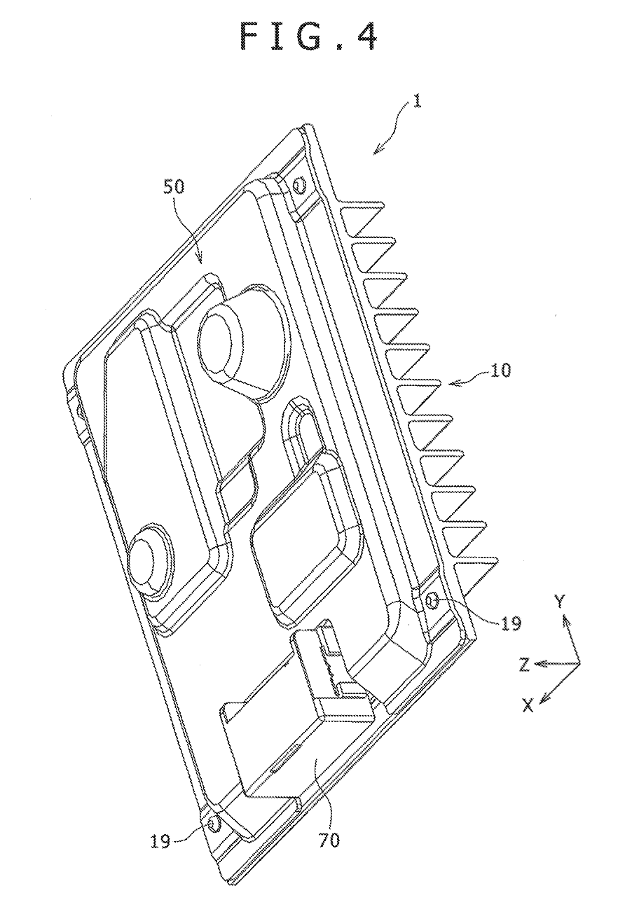

Subsequently, the covering member 50 is placed on the integrated circuit board 30 and the heat sink 10 in such a way that the four projection portions 17 are inserted into the four through holes 53. In this state, the screws 35 are contained in the concave portions provided on the back side of the covering member 50. Thereafter, as shown in FIG. 3, which is a partially enlarged cross-sectional view around the engaging projection portion 19 of the power supply device 1, a tip end portion 55 in the projection portion 17 passed through the through hole 53 is sandwiched between jigs 20a and 20b to be crushed, and thereby the tip end portion 55 is plastically deformed from the shape indicated by the dotted line to the shape indicated by the solid line. In this manner, by deforming the tip end portion 55 to be incapable of passing through the through hole 53, the projection portion 17 is plastically deformed to form the engaging projection portion 19, and the heat sink 10 and the covering member 50 are integrated, to thereby configure the power supply device 1 shown in a perspective view in FIG. 4. As shown in FIG. 3, the engaging projection portion 19 includes a hole disposition part 19a disposed within the through hole 53, and an engaging part 19b positioned closer to the tip end side than the hole disposition part 19a and having a shape incapable of passing through the through hole 53. In the state in which the heat sink 10 and the covering member 50 are integrated, some of the plurality of the electronic components 31 is thermally connected to the back surface of the covering member 50 via the radiation gel 36 (refer to FIG. 1). The radiation gel 36 also has a role of insulating some of the electronic components 31 from the covering member 50. By configuring the radiation gel 36 in the gel state to be freely deformable, dimensional tolerance in design can be absorbed by the radiation gel 36, and it is possible to thermally connect some of the electronic components 31 to the covering member 50 securely.

FIG. 5 is a perspective view of the covering member 50 as viewed from a back side. As shown in FIG. 5, the covering member 50 includes a reference surface 61, at least one concave portion 62 and at least one convex portion 63. The reference surface 61 is configured with a flat surface substantially perpendicular to the Z direction. The concave portion 62 is configured to be recessed from the reference surface 61 toward a side opposite to a side of the circuit board 30 in the Z direction, whereas the convex portion 63 projects from the reference surface 61 toward the circuit board 30 in the Z direction.

A bottom surface 62a the concave portion 62 is configured with a flat surface substantially perpendicular to the Z direction. Regarding the high-height component 32 on the tip end portion of which the radiation gel is disposed, the radiation gel 36 contacts both of the bottom surface 62a and the tip end side of the high-height component 32. As a result, the high-height component 32 is thermally connected to the covering member 50 via the radiation gel 36. The high-height component 32 thermally connecting to the bottom surface 62a of the covering member 50 constitutes a high-height thermally connecting component (a member having high height and thermally connecting to the second member (the covering member 50)) 42. Moreover, the at least one concave portion 62 includes a large-sized concave portion 67 that thermally connects to the plural coils 38a, 38b and 38c (refer to FIG. 1) as an example of plural high-height components. In this embodiment, in at least one large-sized concave portion 67, there is provided a depth-side concave portion 71 recessed from a bottom surface 67a of the large-sized concave portion 67 toward a side opposite to a side of the circuit board 30 in the Z direction. The electrolytic capacitor 37b that is higher than the coils 38a, 38b and 38c faces a bottom surface 71a of the depth-side concave portion 71 with a gap in the Z direction. The electrolytic capacitor 37b is in the state of not thermally connecting to the covering member 50. The coils 38a, 38b, 38c, 38d and 38e are the high-height components 32 and also the high-height thermally connecting components 42. On the other hand, the electrolytic capacitors 37a and 37b are the high-height components 32. However, the electrolytic capacitors 37a and 37b do not thermally connect to the second member (the covering member 50), and therefore, are not the high-height thermally connecting components. As shown in FIG. 1, on the surface of the covering member 50 corresponding to the large-sized concave portion 67, a convex portion 51a is provided. Moreover, on the surface of the covering member 50 corresponding to the depth-side concave portion 71, a convex portion 51b projecting upwardly from the convex portion 51a in the Z direction is provided. Note that description was given of the case in which the concave portion forming a two-level structure is included in the at least one large-sized concave portion 67. In this manner, at least one concave portion 62b having the depth-side concave portion 71 recessed from the bottom surface 62a toward the side opposite to the side of the circuit board 30 in the Z direction may be included in the at least one concave portion 62, and there may be the high-height components 32, at least a portion of which is contained in the depth-side concave portion 71. Here, the at least one concave portion having the depth-side concave portion may include the large-sized concave portion to which the plural high-height components thermally connect, or may not include such a large-sized concave portion. Moreover, the at least one concave portion may include a concave portion having a structure with at least three levels. Alternately, the at least one concave portion may not include a concave portion having a structure with at least two levels, namely, plural levels.

With reference to FIG. 5 again, a tip end surface 63a of the convex portion 63 is configured with a flat surface substantially perpendicular to the Z direction. At least one low-height component 33 includes at least one low-height thermally connecting component (a member having low height and thermally connecting to the second member (the covering member 50)) 43. The radiation gel 36 contacts both of the tip end surface 63a and the tip end side of the low-height thermally connecting component 43. As a result, the low-height thermally connecting component 43 is thermally connected to the covering member 50 via the radiation gel 36 (in the case of the low-height thermally connecting component 43, illustration is omitted). The at least one convex portion 63 includes a large-sized convex portion 68 that thermally connects to a low-height component group 39 (refer to FIG. 1) constituted by the plural low-height thermally connecting components 43. Note that at least one low-height component 33 that does not belong to the low-height component group 39 may include at least one low-height thermally connecting component 43 or may not include the low-height thermally connecting component 43.

Note that when the number of high-height components 32 is larger than the number of low-height components 33, it is preferable that the reference surface 61 is formed at a position higher than an average height between the height of the highest high-height component 32 and the height of the lowest low-height component 33. However, when the number of high-height components 32 is larger than the number of low-height components 33, the reference surface 61 may be formed at the average height between the height of the highest high-height component 32 and the height of the lowest low-height component 33, or may be formed at a height lower than the average height.

Moreover, similarly, when the number of low-height components 33 is larger than the number of high-height components 32, it is preferable that the reference surface 61 is formed at a position lower than an average height between the height of the highest high-height component 32 and the height of the lowest low-height component 33. However, when the number of low-height components 33 is larger than the number of high-height components 32, the reference surface 61 may be formed at the average height between the height of the highest high-height component 32 and the height of the lowest low-height component 33, or may be formed at a height higher than the average height.

FIG. 6 is a perspective view of the power supply device 1 as viewed from the back side. A base member of the heat sink 10 is formed by extrusion molding. That is, the raw material charged into a die (a mold) is squeezed out of the die in the X direction to be formed. Thereafter, by press molding or the like, a part of each of the four corners of the base member is plastically deformed from the back side to the front side, to thereby form concave portions 24 on the back side, and at the same time, form the projection portions 17 (refer to FIGS. 1 and 3) on the front side, and further, by pressing, rolling tap, cutting or the like, the screw holes 15 are formed at predetermined positions. In this manner, the heat sink 10 before the covering member 50 is attached is formed.

Since the base member of the heat sink 10 is formed by squeezing the raw material out of the die in the X direction, the plural radiator fins 12 formed on the back side of the heat sink 10 are arranged in parallel, and each radiator fin 12 extends linearly in the X direction. Moreover, due to forming the base member of the heat sink 10 by extrusion molding, there exists a plane P1 including the Y direction and the Z direction, with which the plural radiator fins 12 are substantially symmetrical. Note that in this embodiment, plural radiator fins 12 are disposed in the Y direction at substantially regular intervals. As a result, in this embodiment, there also exists a plane P2 including the X direction and the Z direction, with which the plural radiator fins 12 are substantially symmetrical.

As described above, the power supply device 1 of the present disclosure converts the input power to generate the output power. Moreover, the power supply device 1 has the heat sink 10 including the circuit board placement surface 11 and the circuit board 30 disposed on the circuit board placement surface 11 of the heat sink 10. Moreover, the power supply device 1 includes the covering member 50 that covers the side opposite to the side of the heat sink 10 of the circuit board 30 in the thickness direction (the Z direction), and the plural electronic components 31 mounted on the circuit board 30. Moreover, the plural electronic components 31 include at least one high-height component 32 and at least one low-height component 33 having height lower than the high-height component 32. Moreover, the covering member 50 includes: the reference surface 61; at least one concave portion 62 recessed from the reference surface 61 toward a side opposite to a side of the circuit board 30 in the Z direction; and at least one convex portion 63 projecting from the reference surface 61 toward the side of the circuit board 30 in the Z direction. Alternatively, the power supply device 1 comprises the circuit board 30 with a side 84 placed on the circuit board placement surface 11 of the heat sink 10; the covering member 50 that covers another side 85 of the circuit board 30 opposite in the Z direction to the side 84 of the circuit board 10 placed on the circuit board placement surface 11; and the plurality of electronic components 31 mounted on the another side 85 of the circuit board 30. Moreover, the plurality of electronic components 31 includes at least one high-height component 32 and at least one low-height component 33 having a height lower than the high-height component relative to the another side of the circuit board 30. Moreover, the covering member 50 includes a reference surface 61, at least one concave portion 62 recessed from the reference surface 61 away from the another side 85 of the circuit board 30 in the Z direction, and at least one convex portion 63 projecting from the reference surface 61 toward the another side 85 of the circuit board 30 in the Z direction. Moreover, the at least one high-height component 32 includes at least one high-height thermally connecting component 42, the tip end portion of which is thermally connected to the bottom surface 62a of the concave portion 62, and the at least one low-height component 33 includes at least one low-height thermally connecting component 43, the tip end portion of which is thermally connected to the tip end surface 63a of the convex portion 63. Note that the high-height component 32 may be defined as an electronic component 31 having a height not less than the height of the lowest high-height thermally connecting component 42 of the at least one high-height thermally connecting component 42. Moreover, the low-height component 33 may be defined as an electronic component 31 having a height not more than the height of the highest low-height thermally connecting component 43 of the at least one low-height thermally connecting component 43. Moreover, a middle-height component may not exist. However, the middle-height component may be defined as an electronic component 31 which is higher than the highest low-height thermally connecting component 43 and lower than the lowest high-height thermally connecting component 42.

Consequently, since the reference surface 61 has the height between the height of the high-height component 32 and the height of the low-height component 33, the depth of the concave portion 62 becomes the depth from the reference surface 61 that is higher than the tip end of the low-height component 33, and therefore, the depth becomes shallower than a case in which the tip end of the low-height component 33 is used as the reference. Accordingly, the degree of plastic deformation in forming the concave portion 62 can be lowered compared to when the tip end of the low-height component 33 is used as the reference. Therefore, the tensile stress in forming the concave portion 62 can be reduced. Moreover, similarly, the height of the convex portion 63 is the height from the reference surface 61, which is lower than the height of the tip end of the high-height component 32. Therefore, the height of the convex portion 63 is lowered compared to when the tip end of the high-height component 32 is used as the reference. Accordingly, the degree of plastic deformation in forming the convex portion 63 can be lowered compared to when the tip end of the high-height component 32 is used as the reference. Therefore, the tensile stress in forming the convex portion 63 can be reduced. As a result, in forming the concave portion 62 or the convex portion 63, the covering member 50 can be made less likely to be broken, and strength of the covering member 50 can be increased.

Further, since the tip end portion of the at least one high-height thermally connecting component 42 is thermally connected to the bottom surface 62a of the concave portion 62, heat removal from the tip end side of the at least one high-height thermally connecting component 42 can be effectively performed. Moreover, since the tip end portion of the at least one low-height thermally connecting component 43 is thermally connected to the tip end surface 63a of the convex portion 63, heat removal from the tip end side of the at least one low-height thermally connecting component 43 can be effectively performed. Consequently, heat removal from the tip end side of the plural electronic components 42 and 43 can be effectively performed.

Moreover, the reference surface 61 may be a flat surface substantially perpendicular to the Z direction.

According to this configuration, it becomes easier to form the concave portion 62 and the convex portion 63, and the covering member 50 can thereby be easily formed.

Moreover, the thickness of the heat sink 10 in the Z direction may be larger than the thickness of the covering member 50.

The heat sink 10 has the circuit board placement surface 11. Therefore, the contact area contacting with the circuit board 30 is large, and the heat from the electronic components 31 is likely to be transferred. Consequently, according to this configuration, thickness of the heat sink 10 is larger than the thickness of the covering member 50, and the heat sink 10 has large heat capacity, which means that the effect of the heat removal in the electronic components 31 can be increased.

Further, by making the thickness of the heat sink 10 larger than the thickness of the covering member 50, the base member of the heat sink 10 can be formed with ease by extrusion molding, and the covering member 50 can be formed with ease by a drawing press process using the sheet metal. Consequently, it is possible to form the heat sink 10 easily and inexpensively, and to form the covering member 50 with ease into the complex shape.

Moreover, at least one of including the large-sized concave portion 67, a bottom 67b of which is thermally connected to respective tip end portion 42a of the plural high-height thermally connecting components 42 in the at least one concave portion 62, and including the large-sized convex portion 68, a tip end surface 68a of which is thermally connected to respective tip end portion 43a of the plural low-height thermally connecting components 43 in the at least one convex portion 63, may be satisfied.

According to this configuration, compared to a case in which the concave portion or the convex portion is formed for each electronic component thermally connected to the second member, it is possible to reduce the degree of plastic deformation in forming the covering member 50. Consequently, it is possible to further suppress breaking of the covering member 50, and to further increase the strength of the covering member 50.

Moreover, the heat sink 10 may include plural radiator fins 12 that are integrally formed.

According to this configuration, it is possible to further improve radiation properties of the heat sink 10, and to perform heat removal of the electronic components 31 more efficiently. It is possible to further perform heat removal of the electronic components 31 more efficiently, so that the thickness of the covering member 50 can be reduced. Consequently, the power supply device 1 can be configured compactly.

Moreover, it may be possible for each radiator fin 12 to extend linearly, and for plural radiator fins 12 to be disposed in parallel. Moreover, there may be a plane P1, which includes the Z direction and the Y direction and with which the plural radiator fins 12 are substantially symmetry. Moreover, the covering member 50 may be configured with a sheet metal. Alternatively, the plurality of radiator fins 12 may extend linearly in parallel in the X direction, and the plurality of radiator fins 12 may be aligned in the Y perpendicular to both of the X direction and the Z direction. Moreover there may exist the plane P1 including the Z direction and the Y direction, the plurality of radiator fins 12 being substantially symmetrical with respect to the plane P1, and the covering member 50 may be configured with sheet metal.

According to this configuration, since each radiator fin 12 extends linearly and plural radiator fins 12 are disposed in parallel, the base member of the heat sink 10 can be formed by extrusion molding. Consequently, compared to a case in which the heat sink 10 is formed by other methods, for example, by die casting or with sheet metal, the heat sink 10 can be formed easily and inexpensively to a great degree. Moreover, since the covering member 50 is configured with sheet metal, the complex shape can be formed with ease.

Moreover, it may be possible for the heat sink 10 to include the engaging projection portions 19 projecting toward a side of the covering member 50 in the Z direction, whereas the covering member 50 may include the through holes 53. Moreover, in the engaging projection portion 19, the hole disposition part 19a disposed within the through hole 53, and the engaging part 19b positioned closer to the tip end side of the engaging projection portions 19 than the hole disposition part 19a and having a shape incapable of passing through the through hole 53 may be included.

According to this configuration, it is possible to attach the covering member 50 to the heat sink 10 easily and inexpensively.

Moreover, the heat sink 10 may be manufactured by plastically deforming the base member formed by the extrusion molding. Alternatively, heat sink 10 may be a plastically deformed extrusion molded base member.

According to this configuration, it is possible to manufacture the heat sink 10 having a large thickness and large heat capacity easily and inexpensively.

Moreover, at least one concave portion 62b having the depth-side concave portion 71 recessed from the bottom surface 62a toward the side opposite to the side of the circuit board 30 in the Z direction may be included in the at least one concave portion 62, and there may be the high-height components 32, at least a portion of which is contained in the depth-side concave portion 71.

According to this configuration, it is possible not only to increase flexibility in arrangement of the plural high-height components 32, but also to further suppress breaking of the heat remover that performs heat removal (the second member, the covering member 50). Note that it may be possible for the power supply device to include at least one depth-side concave portion, and to include, in the at least one depth-side concave portion, the depth-side concave portion containing a portion of each of the plural high-height components. Moreover, each high-height component, a part of which is contained in the depth-side concave portion may be the high-height thermally connecting component thermally connecting to the bottom surface of the depth-side concave portion, or may not be the high-height thermally connecting component.

Moreover, the headlight 91 of the present disclosure includes the power supply device 1 of the present disclosure and the light source 92 to which the power is supplied from the power supply device 1.

According to this configuration, in the power supply device 1, the heat removal from the tip end side of the plural electronic components 42 and 43 thermally connected to the covering member 50 can be performed, and damage caused by heat in the plural electronic components 42 and 43 can thereby be suppressed. Moreover, breaking of the covering member 50 that performs the heat removal of heat from the tip end side of the plural electronic components 42 and 43 can also be suppressed.

Moreover, the automobile 90 as an example of a moving body includes the headlight 91 of the present disclosure.

According to this configuration, in the power supply device 1 that supplies power to the light source 92 of the headlight 91, it is possible to suppress damage caused by heat in the plural electronic components 42 and 43 thermally connected to the covering member 50. Moreover, breaking of the covering member 50 that performs the heat removal of heat from the tip end side of the plural electronic components 42 and 43 can also be suppressed.

Note that the present disclosure is not limited to the above-described embodiment and modified examples thereof, and various changes and modifications are available within the matters described in the claims of the present application and within an equivalent range thereof.

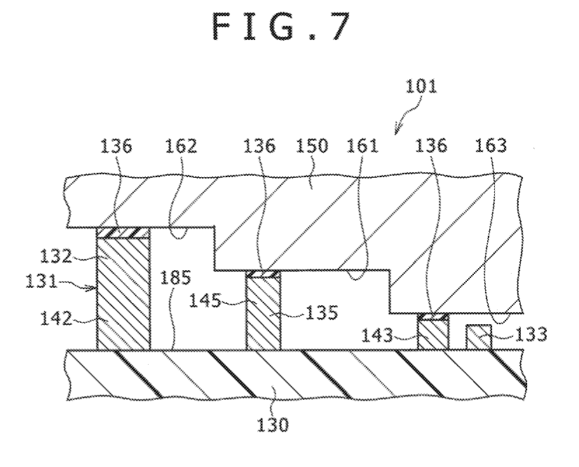

For example, in the above-described embodiment, description was given of the case in which the plural electronic components 31 included the at least one high-height thermally connecting component 42 thermally connected to the bottom surface 62a of the concave portion 62 and the at least one low-height thermally connecting component 43 thermally connected to the tip end surface 63a of the convex portion 63. Moreover, the power supply device 1 did not include electronic components thermally connected to the reference surface 61. However, as shown in FIG. 7, namely, a schematic cross-sectional view of a part of a power supply device 101 according to a modified example including a middle-height thermally connecting component 145, a covering member 150 as the second member may include: a reference surface 161; at least one concave portion 162 recessed from the reference surface 161 toward a side opposite to a side of the circuit board 130 in the thickness direction of the circuit board 130; and at least one convex portion 162 projecting from the reference surface 161 toward the side of the circuit board 130 in the thickness direction. Moreover, plural electronic components 131 may include at least one middle-height component 135 having a height relative to another side 185 of the circuit board 130 lower than a high-height component 132 and higher than a low-height component 133. The at least one middle-height component 135 may include at least one middle-height thermally connecting component (of the middle-height components, electronic components thermally connecting to the second member (the covering member 150)) 145, a tip end portion of which is thermally connected to the reference surface 161. Note that in FIG. 7, the reference number 136 indicates the radiation gel described in the above embodiment. Moreover, in the modified example shown in FIG. 7, as described above, the high-height component 132 may be defined as an electronic component 131 having a height not less than the height of the lowest high-height thermally connecting component 142 of the at least one high-height thermally connecting component 142. Moreover, the low-height component 133 may be defined as an electronic component 131 having a height not more than the height of the highest low-height thermally connecting component 143 of the at least one low-height thermally connecting component 143. Moreover, the middle-height component 135 may be defined as an electronic component 131 which is higher than the highest low-height thermally connecting component 143 and lower than the lowest high-height thermally connecting component 142.

According to the modified example, it is possible to thermally connect the middle-height thermally connecting component 145 to the covering member 150 as the second member. Consequently, damage caused by the heat in the middle-height thermally connecting component 145 can be suppressed, and life of the middle-height thermally connecting component 145 can thereby be extended. Further, even though the middle-height component 135 exists, it is unnecessary to form concave and convex portions for thermally connecting the middle-height component 135 to the covering member 150. As a result, the tensile stress caused by existence of the middle-height component 135 does not occur in the cover, and therefore, the covering member 150 is not broken due to existence of the middle-height component 135.

Moreover, description was given of the case in which the reference surface 61, the bottom surface of the concave portion 62 and the tip end surface of the convex portion 63 were flat surfaces substantially perpendicular to the Z direction. However, at least one of the reference surface, the bottom surface of the concave portion and the tip end surface of the convex portion may not be the flat surface substantially perpendicular to the Z direction. For example, the at least one surface may be an inclined surface inclined with respect to the flat surface substantially perpendicular to the Z direction or a curved surface. Moreover, description was given of the case in which the thickness of the heat sink 10 as the first member was larger than the thickness of the covering member 50 as the second member. However, the thickness of the heat sink (the first member) may be not more than the thickness of the covering member (the second member).

Moreover, description was given of the case in which at least one concave portion 62 included the large-sized concave portion 67 thermally connected to the plural high-height components 32 and at least one convex portion 63 included the large-sized convex portion 68 thermally connected to the plural low-height components 33. However, it may be possible for the at least one concave portion to not include the large-sized concave portion thermally connected to the plural high-height thermally connecting components, and for the at least one convex portion to not include the large-sized convex portion thermally connected to the plural low-height thermally connecting components either. Moreover, it may be possible for only one of the inclusion of the large-sized concave portion thermally connected to the plural high-height thermally connecting components in the at least one concave portion, and the inclusion of the large-sized convex portion thermally connected to the plural low-height thermally connecting components in the at least one convex portion, to hold true.

Moreover, description was given of the case in which the heat sink 10 included the plural radiator fins 12 disposed in parallel. However, it may be possible for the heat sink as the first member to include plural radiator fins that are not in parallel with each other, or only one radiator fin, or to not include the radiator fin at all. Moreover, description was given of the case in which there was a plane P1, which included the Z direction and the Y direction and with which the plural radiator fins 12 were substantially symmetrical. However, a plane, which includes the Z direction and the Y direction and with which the plural radiator fins are substantially symmetrical, may not exist. Moreover, description was given of the case in which there was a plane P2, which included the Z direction and the X direction and with which the plural radiator fins were substantially symmetrical. However, a plane, which includes the Z direction and the X direction and with which the plural radiator fins are substantially symmetrical, may not exist.

Moreover, description was given of the case in which the heat sink 10 and the covering member 50 were integrated by use of the through holes 53 and the engaging projection portions 19. However, the first member and the second member may be integrated by screwing, or may be integrated by an adhesive or welding.

Moreover, description was given of the case in which the heat sink 10 was formed by use of extrusion molding, and the covering member 50 was formed by the drawing press process using sheet metal. However, the first member may be formed without using the extrusion molding, and, for example, may be formed by die casting, the drawing press process using sheet metal, or the like. Moreover, the second member may not be formed by the drawing press process using sheet metal, and may be formed, for example, by die casting or the like.

Moreover, all of at least one high-height component may be a high-height thermally connecting component thermally connected to the second member, or the at least one high-height component may include an electronic component that is not a high-height thermally connecting component thermally connected to the second member. Moreover, all of at least one low-height component may be a low-height thermally connecting component thermally connected to the second member, or the at least one low-height component may include an electronic component that is not a low-height thermally connecting component thermally connected to the second member. Moreover, the power supply device may not include the middle-height component, or may include at least one middle-height component. When the power supply device includes the at least one middle-height component, all of the at least one middle-height component may be a middle-height thermally connecting component thermally connected to the second member, or the at least one middle-height component may include an electronic component that is not a middle-height thermally connecting component thermally connected to the second member. Moreover, description was given of the case in which the power supply device 1 supplied the power to the light source of the headlight in the moving body, and for example, the case in which the power is supplied to the light source 92 of the headlight 91 in the automobile 90 was described. However, the power supply device may supply the power to a light source of an illumination device other than the headlight of the moving body, or may supply the power to a light source of an illumination device that is irrelevant to the moving body.

It should be noted that the first member (the heat sink), the base member of which is formed by extrusion molding and to which the circuit board is fastened, may be used for a power supply device including a covering member without a reference surface, concave portions and convex portions on a back side thereof, and in particular, the first member may be used for a power supply device of a headlight in a moving body. In detail, the first member (the heat sink) may be used for a power supply device including a covering member with only a flat surface on a back side thereof. Alternately, the first member (the heat sink) may be used for a power supply device including a covering member with only a flat surface and at least one concave portion on a back side thereof. Alternately, the first member (the heat sink) may be used for a power supply device including a covering member with only a flat surface and at least one convex portion on a back side thereof. If such a power supply device is manufactured, all the working effects caused by forming the base member of the first member by extrusion molding can be obtained. For example, the first member having large heat capacity and capable of effectively performing heat removal for the electronic components can be formed easily and inexpensively by using extrusion molding. Moreover, it is possible to form plural radiator fins on the first member with ease. By providing the plural radiator fins, heat removal of the electronic components can be performed more effectively. Further, when the plural radiator fins are provided, radiation properties of the first member (the heat sink) can be improved, and accordingly, radiation properties of the covering member can be reduced. Consequently, it is possible to reduce the thickness of the covering member, and the power supply device can be formed compactly.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A power supply device that converts input power to generate output power, the device comprising:
a first member including a circuit board placement surface;
a circuit board with a side placed on the circuit board placement surface of the first member;
a second member that covers another side of the circuit board opposite in a thickness direction to the side of the circuit board placed on the circuit board placement surface; and
a plurality of electronic components mounted on the another side of the circuit board, wherein
the plurality of electronic components include at least one high-height component and at least one low-height component having a height lower than the high-height component relative to the another side of the circuit board,
the second member includes a reference surface, at least one concave portion recessed from the reference surface away from the another side of the circuit board in the thickness direction, and at least one convex portion projecting from the reference surface toward the another side of the circuit board in the thickness direction,
the at least one high-height component includes at least one high-height thermally connecting component, a tip end portion of which is thermally connected to a bottom surface of the concave portion, and
the at least one low-height component includes at least one low-height thermally connecting component, a tip end portion of which is thermally connected to a tip end surface of the convex portion.

2. The power supply device according to claim 1, wherein the reference surface is a flat surface substantially perpendicular to the thickness direction.

3. The power supply device according to claim 1, wherein a thickness of the first member in the thickness direction is larger than a thickness of the second member.

4. The power supply device according to claim 1, wherein
the plurality of electronic components include at least one middle-height component having a height relative to the another side of the circuit board lower than the high-height component and higher than the low-height component, and
the at least one middle-height component include at least one middle-height thermally connecting component, a tip end portion of which is thermally connected to the reference surface.

5. The power supply device according to claim 1, wherein
at least one of:
including a large-sized concave portion, a bottom of which is thermally connected to respective tip end portions of a plurality of the high-height thermally connecting components, in the at least one concave portion; and
including a large-sized convex portion, a tip end surface of which is thermally connected to respective tip end surfaces of a plurality of the low-height thermally connecting components, in the at least one convex portion, is satisfied.

6. The power supply device according to claim 1, wherein the first member includes a plurality of radiator fins that are integrally formed.

7. The power supply device according to claim 6, wherein
the plurality of radiator fins extending linearly in parallel in an extending direction, the plurality of radiator fins being aligned in an alignment direction perpendicular to both of the extending direction of the radiator fins and the thickness direction,
there exists a plane including the thickness direction and the alignment direction, the plurality of radiator fins being substantially symmetrical with respect to the plane, and
the second member is configured with sheet metal.

8. The power supply device according to claim 1, wherein
the first member includes an engaging projection portion projecting toward the second member in the thickness direction and the second member includes a through hole, and
the engaging projection portion includes a hole disposition part disposed within the through hole, and an engaging part positioned closer to a tip end side of the engaging projection portion than the hole disposition part, the engaging part having a shape incapable of passing through the through hole.

9. The power supply device according to claim 1, wherein the first member is a plastically deformed extrusion molded base member.

10. The power supply device according to claim 1, wherein
the at least one concave portion includes at least one further concave portion recessed from the bottom surface further away from the another side of the circuit board in the thickness direction, and
there exists the high-height component, at least a portion of which is contained in further concave portion.

11. A headlight comprising:
the power supply device according to according to claim 1; and
a light source supplied with power from the power supply device.

12. A moving body comprising the headlight according to claim 11.
